(19) United States
(12) Patent Application Publication
(10) Pub. No.: US 2014/0109948 A1
(43) Pub. Date: Apr. 24, 2014

(54) THERMOELECTRIC MODULE, THERMOELECTRIC DEVICE COMPRISING THE SAME, AND PROCESS FOR PREPARING THE THERMOELECTRIC ELEMENT

(71) Applicant: Samsung Electronics Co., Ltd., Suwon-si (KR)

(72) Inventors: Kyu-hyoung LEE, Hwaseong-si (KR); Sang-il KIM, Seoul (KR); Se-yun KIM, Seoul (KR); Eun-sung LEE, Hwaseong-si (KR)

(73) Assignee: Samsung Electronics Co., Ltd., Suwon-si (KR)

(21) Appl. No.: 13/904,365

(22) Filed: May 29, 2013

(30) Foreign Application Priority Data
Oct. 19, 2012 (KR) 10-2012-0116745

(51) Int. Cl. H01L 35/08; H01L 35/34

(52) U.S. Cl. CPC H01L 35/08; H01L 35/34
USPC 136/203; 136/200; 136/205; 438/54

(57) ABSTRACT

A thermoelectric module including: an n-type thermoelectric element; a p-type thermoelectric element; a diffusion blocking layer bonded integrally on each of a top and a bottom surface of the n-type thermoelectric element and on each of a top and a bottom surface of the p-type thermoelectric element; an electrode on the n-type thermoelectric element and on the p-type thermoelectric element; and a bonding layer disposed between the electrode and at least one of the n-type thermoelectric element and the p-type thermoelectric element, wherein the bonding layer includes an amorphous metal.

### CROSS-REFERENCE TO RELATED APPLICATIONS

This application claims priority to and the benefit of Korean Patent Application No. 10-2012-0116745, filed on Oct. 19, 2012, and all the benefits accruing therefrom under 35 U.S.C. §119, the content of which is incorporated herein in its entirety by reference.

### BACKGROUND

1. Field

The present disclosure relates to a thermoelectric module, a thermoelectric device including the same, and methods of manufacturing the same. The present disclosure further relates to thermoelectric modules having improved efficiency.

2. Description of the Related Art

The thermoelectric effect refers to reversible and direct energy conversion between heat and electricity. Thermoelectric effect occurs because of a movement of a charge carrier in the material from a hot side to a cold side; and hence, a movement of an electron and an electron hole.

A thermoelectric element that induces the thermoelectric effect is referred to by various names such as thermoelectric module, Peltier effect device, and thermoelectric cooler, and it is a small heat pump that absorbs heat from a low temperature heat source and transfers it to a high temperature heat source.

The thermoelectric module is largely composed of three parts including; an insulating substrate, an n-type semiconductor device or a p-type semiconductor device, and a metal electrode for a thermoelectric module, such a copper electrode. Also, a diffusion blocking layer may be included between the thermoelectric element and the metal electrode to maintain the properties of the thermoelectric module. The thermoelectric element has a base unit including an n-type thermoelectric semiconductor and a p-type thermoelectric semiconductor, and a thermoelectric module generally may include approximately 127 base units, or 127 pairs of thermoelectric elements. To improve performance and efficiency, there remains a need for an improved thermoelectric module.

### SUMMARY

Provided is a thermoelectric module with improved bonding interface properties.

Provided is a thermoelectric device including the thermoelectric module.

Provided is a method of manufacturing the thermoelectric module.

Additional aspects will be set forth in part in the description which follows and, in part, will be apparent from the description.

According to an aspect, a thermoelectric module includes an n-type thermoelectric element; a p-type thermoelectric element; a diffusion blocking layer bonded integrally on at least one of a top and a bottom surface of the n-type thermoelectric element and on at least one of a top and a bottom surface of the p-type thermoelectric element; an electrode on the n-type thermoelectric element and on the p-type thermoelectric element; and a bonding layer disposed between the electrode and at least one of the n-type thermoelectric element and the p-type thermoelectric element, wherein the bonding layer includes an amorphous metal.

According to another aspect a thermoelectric device includes the thermoelectric module.

According to another aspect, provided is a method of manufacturing a thermoelectric module, the method including: disposing a top electrode and a bottom electrode on a top substrate and a bottom substrate, respectively; disposing a bonding material on at least one of the top electrode and the bottom electrode; interposing a p-type thermoelectric element and an n-type thermoelectric element between the top electrode and the bottom electrode, each of the p-type thermoelectric element and the n-type thermoelectric element having a diffusion blocking layer disposed thereon, the diffusion blocking layer bonded integrally to each of a top and a bottom surface of the p-type thermoelectric element and to each of a top and a bottom surface of the n-type thermoelectric element, wherein the diffusion blocking layer contacts the bonding material if present, to form an electrode structure; and calcining the electrode structure to manufacture the thermoelectric module, wherein the bonding material includes an amorphous metal.

According to an embodiment, by improving bonding interface properties within the electrode and the thermoelectric module, improved mechanical stability may be obtained, and thermoelectric module efficiency may be improved. The thermoelectric module may be used in various areas such as in a thermoelectric device.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic illustration of an embodiment of a thermoelectric module;

FIG. 2 illustrates an embodiment of a top substrate with a top electrode;

FIG. 3 illustrates an embodiment of a bottom substrate with a bottom electrode;

FIG. 4 is a schematic diagram illustrating an embodiment of a cooling process of a thermoelectric module;

FIG. 5 is a schematic diagram illustrating an embodiment of a power generation process of a thermoelectric module;

FIG. 6 is a schematic diagram of an embodiment of a thermoelectric element including a diffusion blocking layer;

FIG. 7 illustrates an embodiment of a process of assembling an electrode, a bonding material, a diffusion blocking layer, and a thermoelectric element on a substrate;

FIG. 8 illustrates an embodiment of a bulk form of a bonding material disposed on a substrate and an electrode;

FIG. 9 illustrates an embodiment of a powder form of a bonding material disposed on a substrate and an electrode;

FIG. 10 illustrates an embodiment of a paste form of a bonding material disposed on a substrate and an electrode;

FIG. 11 illustrates a side view image of a Co—Sb type thermoelectric element with a Cu—Mo diffusion blocking layer, according to Example 1;

FIG. 12 is a photograph illustrating a bond between an electrode and a thermoelectric material; and

FIG. 13 is a graph of resistance (ohm-meters, Ωm) versus temperature (Kelvin, K) illustrating a result of an electrical resistance measurement obtained from Example 1 and Comparative Example 1.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. Expressions such as “at least one of,” when preceding a list of elements, modify the entire list of elements and do not modify the individual elements of the list.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“Transition metal” as defined herein refers to an element of Groups 3 to 12 of the Periodic Table of the Elements.

“Group” means a group of the Periodic Table of the Elements according to the International Union of Pure and Applied Chemistry (“IUPAC”) Group 1-18 group classification system.

“Rare earth” means the fifteen lanthanide elements, i.e., atomic numbers 57 to 71, plus scandium and yttrium. The “lanthanide elements” means the chemical elements with atomic numbers 57 to 71.

To increase the thermoelectric efficiency of a thermoelectric module, an electrode for the thermoelectric element desirably has suitable properties including a coefficient of thermal expansion which is suitably similar to that of a thermoelectric semiconductor element, and is stable at a high temperature. In the case of a traditional thermoelectric element, there is a large difference in the coefficients of thermal expansion between the thermoelectric material and the electrode such that a gap may form on a bonding interface of the thermoelectric element at a high temperature, leading to a faulty bonding.

In general and while not wanting to be bound by theory, a primary factor contributing to a low efficiency of a thermoelectric module can be poor performance of a thermoelectric element. Also, interfacial resistance between a thermoelectric element and a diffusion blocking layer, and an interfacial resistance between the diffusion blocking layer and an electrode is another important factor which can contribute to thermoelectric module efficiency. When the thermoelectric module is in operation, its actual power generation efficiency can be lower than its theoretical thermoelectric module efficiency by greater than 30% due to the interfacial resistance. A primary factor contributing to the interfacial resistance can be a dry joint such as an air space or a crack that is caused by irregular bonding of an interface located between the thermoelectric element and the diffusion blocking layer and by irregular bonding of another interface located between the diffusion blocking layer and the electrode.

During operating of the thermoelectric module, a temperature difference between opposite ends of the thermoelectric module can be very large (greater than few hundred degrees ° C.) such that a mechanical breakdown may occur due to thermal stress. The mechanical breakdown is understood to occur primarily at the weakest area of the module structure; hence, the mechanical breakdown can occur at a bonding interface between the diffusion blocking layer and the electrode.

The thermoelectric module according to an embodiment comprises a bonding material used in the diffusion blocking layer and the bonding interface of the electrode, and by using a bonding material including an amorphous alloy, reduced thermal resistance/electrical resistance, excellent bonding properties, and excellent thermal/mechanical stability may be obtained. Hence, the mechanical stability of a thermoelectric generation module may be improved, and efficiency of a thermoelectric module may be increased.

An amorphous metal that may be used for the bonding layer may be any suitable metal with a glass transition temperature (T_{g}), and a crystallization temperature (Tₓ) lower than the melting point of the thermoelectric material (T_{L}). For example, an amorphous metal with a high electrical conductivity may be used. The amorphous metal may be an alloy, and the alloy may comprise, or be composed primarily of, or consist of Al, Cu, Ni, or Ti, or a combination thereof.

The alloy may comprise any of the alloys listed in Tables 1 through 5, or a combination thereof. The alloys in Tables 1 to 5 may be amorphous. The amorphous alloys listed in Table 1 are alloys with an abundance of Al, the amorphous alloys listed in Table 2 are alloys with an abundance of Cu, the amorphous alloys listed in Table 3 are alloys with abundance of Fe or Ni, the amorphous alloys listed in Table 4 are alloys with abundance of Mg, Mn, or Ca, and the amorphous alloys listed in Table 5 are alloys with abundance of Ti or Zr. However, the amorphous metals are not limited to alloys listed in the Tables 1 to 5.

TABLE 1

| Alloy | T_{g} | Tₓ | T_{L} |
|---|---|---|---|
| Al88Y7Fe5 | 258 | 280 | 1000 |
| Al88Sm8Ni4 | 220 | 241 | 1000 |
| Al87.5Y7Fe5V0.5 | 280 | 340 | 960 |
| Al87.5Y7Fe5Ti0.5 | 275 | 310 | 950 |
| Al87Y7Fe5Ti1 | 270 | 340 | 960 |
| Al86Y7Fe5Ti2 | 280 | 350 | 995 |
| Al85Ni10Ce5 | 246 | 264 | 1000 |
| Al85.35Y8Fe6V0.65 | 285 | 365 | 1010 |
| Al85Y8Fe6V0.65O0.35 | 285 | 355 | 1012 |
| Al85Y8Ni5Co2 | 267 | 297 | 1000 |
| Al85Gd8Ni5Co2 | 281 | 302 | 1000 |
| Al85Dy8Ni5Co2 | 277 | 303 | 1000 |
| Al85Er8Ni5Co2 | 274 | 305 | 1000 |
| Al84Ni10Ce6 | 273 | 286 | 1000 |
| Al84Ni10La6 | 273 | 289 | 845 |
| Al84.35Y8Fe6V0.65O1 | 285 | 355 | 1000 |

TABLE 2

| Alloy | T_{g} | Tₓ | T_{L} |
|---|---|---|---|
| Cu30Ag30Zr30Ti10 | 393 | 427 | 794 |
| Cu40Ni20Zr30Ti10 | 454 | 476 | 944 |
| Cu40Ni5Ag15Zr30Ti10 | 424 | 454 | 797 |
| Cu43Zr43Al7Ag7 | 449 | 521 | 852 |
| Cu46Gd47Al7 | 245 | 266 | |
| Cu46Hf42.5Al7 | 519 | 551 | |
| Cu46Y42.5Al7 | 290 | 319 | |
| Cu46Zr46Al8 | 430 | 513 | 886 |
| Cu46Zr47Al7 | 445 | 504 | |
| Cu47.5Zr40Be12.5 | 425 | 483 | 825 |
| Cu47Ti33Nb11Ni8Si1 | 437 | 459 | 992 |
| Cu47Ti33Zr11In8Si1 | 430 | 460 | 816 |
| Cu47Ti33Zr11Ni6Ag2Si1 | 441 | 465 | |
| Cu47Ti33Zr11Ni6Co2Si1 | 447 | 491 | |
| Cu47Ti33Zr11Ni6Sn2Si1 | 436 | 489 | |
| Cu47Ti33Zr11Ni8Si1 | 447 | 484 | 884 |
| Cu47Ti33Zr9Nb2Ni8Si1 | 455 | 489 | |
| Cu47Ti33Zr9Y2Ni8Si1 | 429 | 456 | |
| Cu50Zr35Ti10Al5 | 427 | 468 | 848 |
| Cu50Zr40Ti10 | 387 | 435 | 880 |
| Cu50Zr43Al7 | 458 | 519 | 903 |
| Cu50Zr45Al5 | 434 | 494 | 862 |
| Cu50Zr50 | 402 | 451 | 957 |
| Cu57Zr28.5Ti9.5Ta5 | 456 | 478 | |
| Cu60Zr30Ti10 | 451 | 473 | 833 |
| Cu60Zr40 | 453 | 503 | 894 |

TABLE 3

| Alloy | T_{g} | Tₓ | T_{L} |
|---|---|---|---|
| Fe65Mn13B17Y3 | 561 | 611 | 1082 |
| Fe67Mn13B17Y3 | 506 | 555 | 1082 |
| Fe67Mo13B17Y3 | 587 | 628 | 1157 |
| Fe70Mo13B17 | 549 | 577 | 1116 |
| Fe72Nb4B20Si4 | 569 | 607 | 1147 |
| (Fe72Nb4B20Si4)96Y4 | 632 | 660 | 1151 |
| Fe74Nb6B20 | 550 | 574 | 1156 |
| Fe74Nb6Y3B17 | 558 | 606 | 1118 |
| Fe77Nb6B17 | 524 | 541 | 1151 |
| Ni20Nb20P20 | 448 | 462 | |
| Ni55Zr12Al11Y22 | 423 | 460 | |
| Ni55Zr34Al11 | 562 | 580 | |
| Ni57.5Zr24Nb11Al7.5 | 576 | 609 | 1078 |
| Ni57.5Zr35Al7.5 | 550 | 575 | 1060 |
| Ni59Zr11Ti16Si2Sn3Nb9 | 569 | 609 | 999 |
| Ni59Zr20Ti16Si2Sn3 | 548 | 604 | 941 |
| Ni60Nb15Zr25 | 570 | 601 | 1132 |
| Ni60Nb30Ta10 | 661 | 688 | 1208 |
| Ni61Zr20Nb7Al4Ta8 | 603 | 661 | 1113 |
| Ni61Zr28Nb7Al4 | 575 | 625 | 1075 |

TABLE 4

| Alloy | T_{g} | Tₓ | T_{L} |
|---|---|---|---|
| Mg65Ag25Gd10 | 202 | 202 | 443 |
| Mg65Cu15Ag10Gd10 | 143 | 186 | |
| Mg65Cu15Ag10Gd10 | 143 | 186 | 402 |
| Mg65Cu15Ag10Y10 | 155 | 196 | 413 |
| Mg65Cu15Ag5Pd5Gd10 | 157 | 199 | 414 |
| Mg65Cu20Ag5Y10 | 152 | 204 | 416 |
| Mg65Cu25Gd10 | 150 | 211 | 406 |
| Mg65Cu25Y10 | 153 | 215 | 457 |
| Mg65Cu7.5Ni7.5Ag5Zn5Gd10 | 167 | 204 | 453 |
| Mg65Cu7.5Ni7.5Ag5Zn5Y10 | 157 | 186 | 455 |
| Mg70Ni10Gd20 | 215 | 237 | |
| Mg75Ni15Gd10 | 190 | 231 | |
| Mg80Ni10Gd10 | 158 | 178 | |
| Mn55Al25Ni10Cu10 | 199 | 267 | 657 |
| Mn55Al25Ni10Cu5Co5 | 205 | 289 | 655 |
| Mn55Al25Ni20 | 220 | 277 | 682 |
| (Mn55Al25Ni10Cu5Co5)96C4 | 220 | 290 | 693 |
| Ca60Mg25Ni15 | 158 | 180 | 410 |
| Ca65Mg15Zn20 | 106 | 139 | 351 |

TABLE 5

| Alloy | T_{g} | Tₓ | T_{L} |
|---|---|---|---|
| Ti34Zr31Cu10Ni8Be17 | 352 | 378 | |
| Ti40Zr25Ni8Cu9Be18 | 348 | 395 | 675 |
| Ti40Zr28Cu9Ni7Be16 | 337 | 357 | |
| Ti45Ni15Cu25Sn3Be7Zr5 | 407 | 468 | 791 |
| Ti49Nb6Zr18Be14Cu7Ni6 | 348 | 375 | |
| Ti50Ni15Cu25Sn3Be7 | 415 | 460 | 849 |
| Ti50Ni15Cu32Sn3 | 413 | 486 | 932 |
| Ti50Zr15Be18Cu9Ni8 | 349 | 389 | 736 |
| Ti51Y4Zr18Be14Cu7Ni6 | 312 | 339 | |
| Ti55Zr18Be14Cu7Ni6 | 312 | 349 | |
| Ti65Be18Cu9Ni8 | 362 | 397 | 863 |
| Zr36Ti24Be40 | 354 | 440 | |
| Zr65Al7.5Cu12.6Ni10Ag5 | 386 | 436 | |
| Zr65Al7.5Cu17.5Ni10 | 380 | 443 | |

Regarding an alloy with an abundance of Al in Table 1, the glass transition temperature is in a range of about 215° C. to about 290° C., an alloy with abundant Cu in Table 2 has a glass transition temperature in a range of about 240° C. to about 520° C., an alloy with an abundance of Fe or Ni in Table 3 has a glass transition temperature in a range of about 420° C. to about 625° C., an alloy with abundant Mg, Mn or Ca in Table 4 has a glass transition temperature in a range of about 100° C. to about 220° C., and an alloy with abundant Ti or Zr in Table 5 has a glass transition temperature in a range of about 310° C. to about 420° C.

If the composition of an amorphous alloy in a metal is represented as an empirical formula of AₐB_{b}C_{c}D_{d}EₑF_{f} (wherein, A, B, C, D, E, F are different elements), for example, an alloy with an abundance of Al in Table 1, A is Al, B is Y or Ni, C is Fe, Ce, Sm, Y, Gd, Dy, Er or La, D is V, Ti or Co, and E is 0, wherein, the ranges of a, b, c, d, and e are 80≦a≦90, 2≦b≦12, 3≦c≦10, 0≦d≦3, and 0≦e≦2, wherein, a+b+c+d+e=100. For an alloy with an abundance of Cu in Table 2, A is Cu, B is Zr, Ti, Y, Gd or Hf, C is Al, Zr, Ti, Ag, Be, Nb, or Ni, D is Ni, Ti, Ag, Al, In, Nb, Ta or Y, E is Si, Ni, Sn, Ag or Co, and F is Si. For an alloy with abundant Fe or Ni in Table 3, B is B, Zr, Nb, Ti or Y, C is Mo, Mn, Nb, Al, Ta, Zr, Ti or P, D is Y, Nb, Al, Si or Sn, E is Al, Y, Si or Sn, and F is Si, wherein, the ranges of a, b, c, d, e, and f are 20≦a≦80, 15≦b≦35, 2≦c≦20, 0≦d≦15, 0≦e≦5, and 0≦f≦3, wherein, a+b+c+d+e+f=100. For an alloy with an abundance of Mg, Mn or Ca in Table 4, A is Mg, Mn or Ca, B is Cu, Al, Ni, Gd, Ag, Y, Zn or Mg, C is Ni, Gd, Ag, Y, Cu or Mg, D is Cu, Ni, Ag, Gd, Y, Pd, Co, Zn or C, E is Ag, Co or Pd, and F is Zn or C, wherein, the ranges of a, b, c, d, e, f are 55≦a≦80, 10≦b≦25, 5≦c≦20, 0≦d≦10, 0≦e≦5, and 0≦f≦5, wherein, a+b+c+d+e+f=100. For an alloy abundant Ti or Zr in Table 5, B is Cu, Zr or Be, C is Ni, Be, Zr or Cu, D is Cu, Al, Ni, Sn, Ag, Y or Nb, E is Ni, Ag, Sn or Be, F is Y, Nb or Zr, wherein, the ranges of a, b, c, and d are 30≦a≦65, 10≦b≦40, 5≦c≦25, 0≦d≦10, 0≦e≦10, and 0≦f≦7, wherein, a+b+c+d+e+f=100.

According to an embodiment, the bonding layer may include about 5 weight percent (weight %) to about 100 weight %, specifically about 3 weight % to about 20 weight % of the amorphous metal, based on a total weight of the bonding layer.

The bonding layer may further include components other than the amorphous metal, such as Ag, Cu, and Mo. The components may be included for reducing contact resistance, increasing bonding properties, or controlling the thermal expansion coefficient.

According to an embodiment, the thickness of the bonding layer including the amorphous metal may be about 1 μm to about 15 μm, specifically about 5 μm to about 10 μm. The thickness of the bonding layer may depend on the proportion of the thickness of the thermoelectric semiconductor. For example, the thickness of the bonding layer may be in a range of about 0.1 percent (%) to about 10%, specifically about 0.5% to about 3%, of the total thickness of the thermoelectric semiconductor element.

In the thickness ranges above, the bonding layer may provide sufficient adhesion between the electrode and the diffusion blocking layer.

The diffusion blocking layer used in the thermoelectric module is suitable to prevent the diffusion of a component of the electrode in the direction of the thermoelectric semiconductor element. The diffusion blocking layer may comprise a metal suitable for bonding efficiency. For example, the diffusion blocking layer may comprise at least one selected from Ti, Pt, Pd, Ti, W, Ni, Si, Ta, TiW, TiN, WN, TaN, and TiWN. The diffusion blocking layer may further or alternatively comprise at least one selected from a silicide of, Ti, Pt, Pd, Ti, W, Ni, and Ta.

The thickness of the diffusion blocking layer may be about 1 μm to about 500 μm, or about 5 μm to about 100 μm, but is not limited thereto. Alternatively, the thickness of the diffusion blocking layer may also depend on the ratio corresponding to the total thickness of the thermoelectric semiconductor element. For example, the thickness of the diffusion blocking layer may be about 0.1% to about 10%, specifically about 0.5% to about 3% of the total thickness of the thermoelectric semiconductor element.

The electrode used in the thermoelectric module may comprise a highly electroconductive material to minimize loss of power provided to the thermoelectric module. For example, the electrode may comprise a highly electroconductive materials such as at least one selected from copper (Cu), copper-molybdenum (Cu—Mo), silver (Ag), gold (Au), and platinum (Pt).

The thermoelectric element used in the thermoelectric module may be at least one thermoelectric semiconductor including at least one element selected from, for example, a transition metal, a rare earth element, a Group 13 element, a Group 14 element, a Group 15 element, and a Group 16 element. As the rare earth element, Y, Ce, and La are specifically mentioned, as the transition metal, at least one of Ti, Zr, Hf, V, Nb, Ta, Cr, Mo, W, Mn, Fe, Co, Ni, Cu, Zn, Ag, and Re are specifically mentioned, as the Group 13 element, at least one of B, Al, Ga, and In are specifically mentioned, as the Group 14 element, at least one of C, Si, Ge, Sn, and Pb are specifically mentioned, as the Group 15 element, at least one of P, As, Sb, and Bi are specifically mentioned, and as the Group 16 element, at least one of S, Se, and Te are specifically mentioned. Examples of the at least one thermoelectric semiconductor include a Bi—Te type thermoelectric semiconductor, a Pb—Te type thermoelectric semiconductor, a Si—Ge type thermoelectric semiconductor, a Fe—Si type thermoelectric semiconductor, or a Sb—Te type thermoelectric semiconductor.

The semiconductor includes at least one element selected from a transition metal, a Group 13 element, a Group 14 element, a Group 15 element, a Group 16 element, wherein the at least one element may be a dopant so as to improve an electrical property. An example of the Bi—Te thermoelectric semiconductor may be a (Bi,Sb)₂(Te,Se)₃ type thermoelectric semiconductor, wherein Sb or Se is used as the dopant, an example of a Co—Sb type thermoelectric semiconductor may be a CoSb₃ type thermoelectric semiconductor, examples of an Sb—Te type thermoelectric semiconductor may be AgSbTe₂ and CuSbTe₂, and examples of a Pb—Te type thermoelectric semiconductor may be PbTe and (PbTe)ₘAgSbTe₂.

The thermoelectric element is bonded to the electrode, and a groove or well may be formed to facilitate bonding. The groove may be circular such that dimensions of the groove correspond to the dimensions of an end portion of the thermoelectric element.

The electrode may be disposed on a substrate, such as an electrically insulating substrate, and the substrate may comprise a material that exhibits an exothermic or an endothermic reaction when a power supply is supplied to the thermoelectric module. For example, in the case of an electrically insulating ceramic such as alumina (Al₂O₃), aluminum nitride (AlN), boron nitride (BN), zirconia (ZrO₂), and silica (SiO₂), technology known in the field may be used for determining thickness and form.

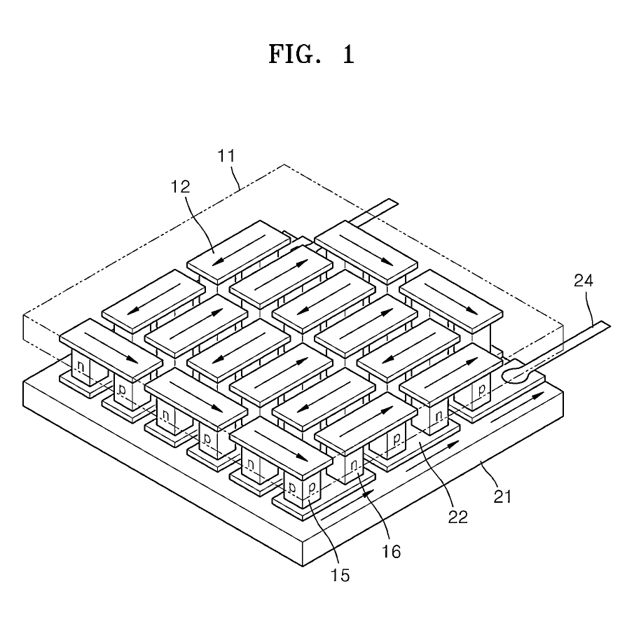

An example of the thermoelectric module according to an embodiment is shown in FIG. 1.

As shown in FIG. 1, top and bottom exteriors are formed by a top substrate 11 and a bottom substrate 21. Between the top substrate 11 and the bottom substrate 21, p-type thermoelectric elements 15, and n-type thermoelectric elements 16 are alternately arranged, and the top electrode 12 and the bottom electrode 22 are respectively located between the thermoelectric elements 15 and 16 and the top substrate 11 and the bottom substrate 21. The top electrode 12 and the bottom electrode 22 guide a flow of power when the power is supplied to the thermoelectric module, and the electrodes may contact at a bottom surface of the top substrate 11 and a top surface of a top electrode 12, and at a bottom surface of a bottom electrode 22 and an upper surface of the bottom substrate 21.

The top electrode 12 and the bottom electrode 22, and the thermoelectric elements 15 and 16 are alternately arranged such that electricity may flow, and as a result, when power is supplied to the thermoelectric element, the p-type semiconductor element 15, and the n-type semiconductor element 16 may form an electrical series in a direction of the arrows in FIG. 1.

The thermoelectric module may include a plurality of thermoelectric couples inclusive of the p-type thermoelectric element 15 and the n-type thermoelectric element 16, for example, about 50 to about 200, specifically about 100 to about 150 of the thermoelectric couples.

Both of the diffusion blocking layer 14 and the bonding layer may be located between the top electrode 12 and the bottom electrode 22, and between the thermoelectric elements 15 and 16.

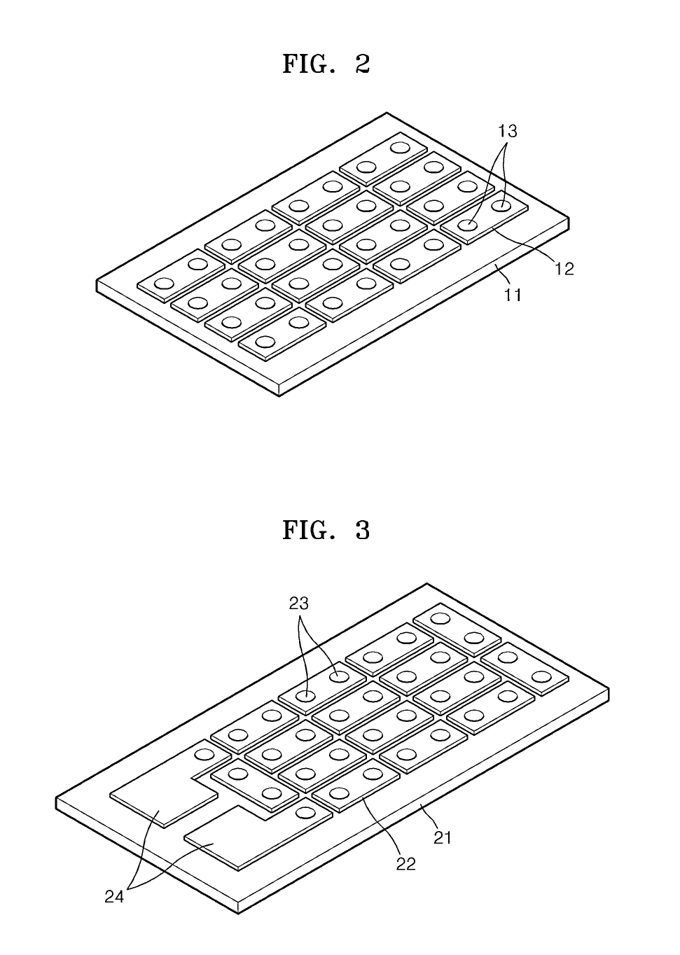

FIG. 2 illustrates a structure with a groove 13 disposed on the top electrode 12 which is disposed on the top substrate 11. Likewise, as shown in FIG. 3, a groove 23 may be disposed on the bottom electrode 22 which is disposed on the bottom substrate 21.

Due to the grooves 13 and 23, the bonding material for bonding the thermoelectric elements 15 and 16 on the electrodes is easily arranged, and easily bonded. The grooves 13 and 23 may have, for example, a depth of about 0.01 millimeter (mm) to about 2 mm, specifically about 0.1 mm to about 1 mm.

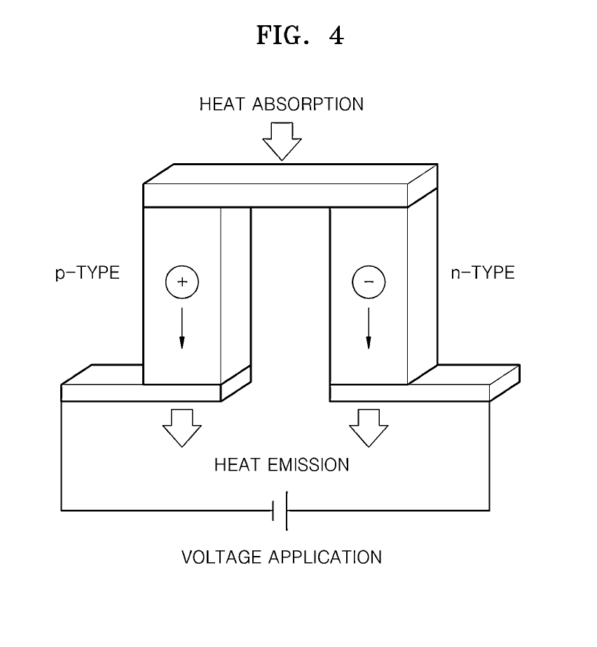

In the thermoelectric module, a lead wire 24 is connected such that the module can electrically connect to the exterior. When direct current (“DC”) voltage is applied to both ends of the lead wire 24, heat moves from a heat sink to a heat generator in a direction of the flow of electrons in the n-type thermoelectric element 16, and in a direction of the flow of an electron hole in the p-type thermoelectric element 15 as shown in FIG. 4. As a result, the temperature of the heat sink decreases over time while temperature of the heat generator increases. If polarity of the applied voltage is changed, the locations of the heat sink and the heat generator are reciprocally changed, and the direction of the heat flow reverses. This phenomenon arises due to the difference in potential energy between electrons in a metal. Hence, for an electron to move from a metal with a low potential energy to a metal with a high potential energy, external energy is used such that heat energy is taken away at the point of contact. In the opposite case, however, heat energy is released in an endothermic reaction (cooling). The endothermic reaction (cooling) is proportional to the flow of electricity and the number of thermoelectric element couples (a thermoelectric element couple of the n-type and the p-type) in the thermoelectric module.

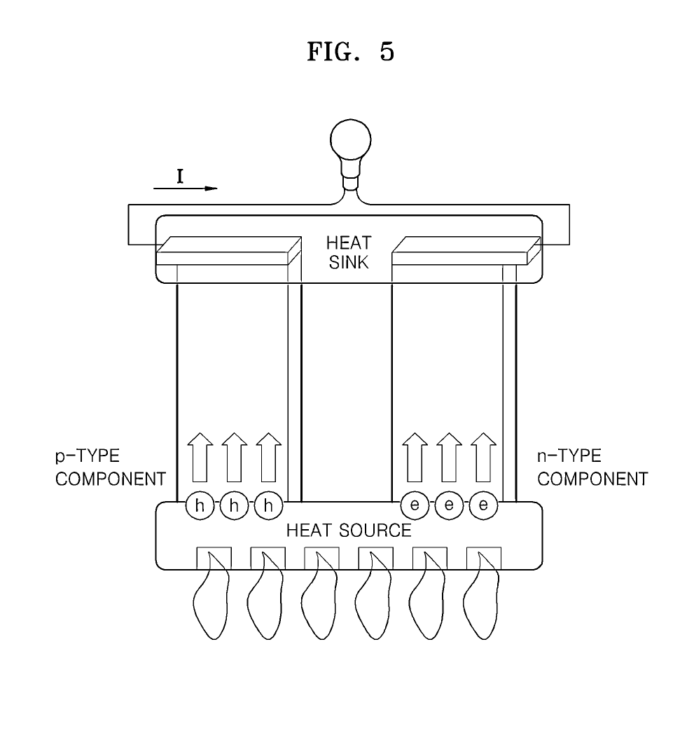

FIG. 5 illustrates the process of electrical energy generation using energy from a heat source. Because an electron hole h moves from the p-type thermoelectric element, and an electron e moves from the n-type thermoelectric semiconductor due to heat from the heat source, electrical energy may be generated.

According to an embodiment, power generation efficiency may be improved by bonding the diffusion blocking layers between the thermoelectric elements 15 and 16, and between the top electrode 12 and the bottom electrode 22 using the bonding material that may form a bonding interface with reduced thermal resistance, reduced electrical resistance, and improved bonding properties including improved mechanical strength.

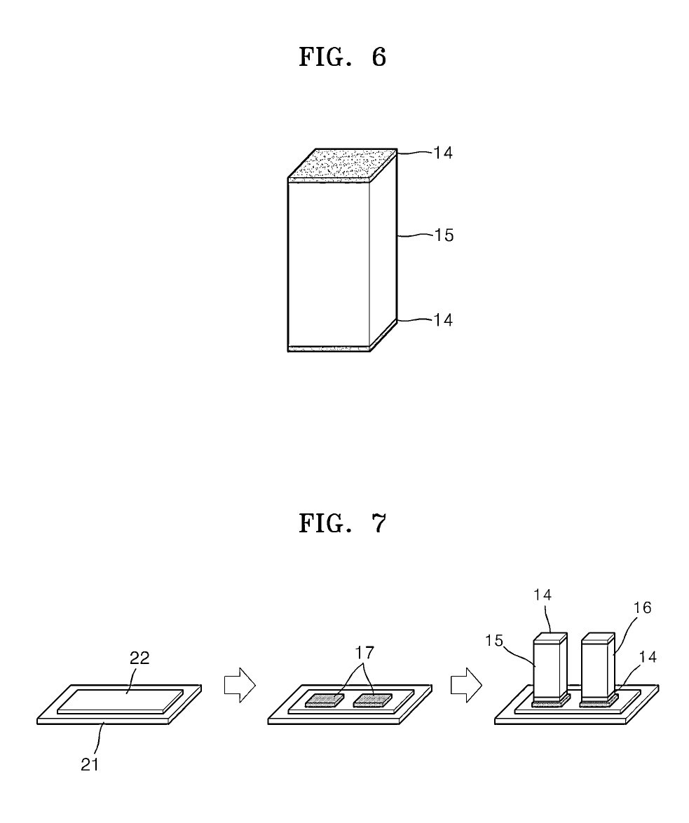

FIG. 6 illustrates a schematic diagram of a thermoelectric element wherein the diffusion blocking layers 14 are formed on the top and on the bottom surfaces of the thermoelectric element 15. The diffusion blocking layer is the same as the above.

A process of forming a thermoelectric element is shown in FIG. 7, wherein the diffusion blocking layer is integrally formed at the top surface and the bottom surface, the diffusion blocking layer is bonded using the bonding layer, and the process is shown in FIG. 7. As shown in FIG. 7, the bottom electrode 22 is disposed on the bottom substrate 21, and a prescribed amount of bonding material 17 is disposed on the bottom electrode 22. On the bonding material 17, the p-type thermoelectric element 15 including the diffusion blocking layer, and the n-type thermoelectric element 16 are bonded. According to an embodiment, the bonding material 17 may include an amorphous metal. The bonding material may be present on one or both ends of the p-type thermoelectric element 15 and on one or both ends of the n-type thermoelectric element 16.

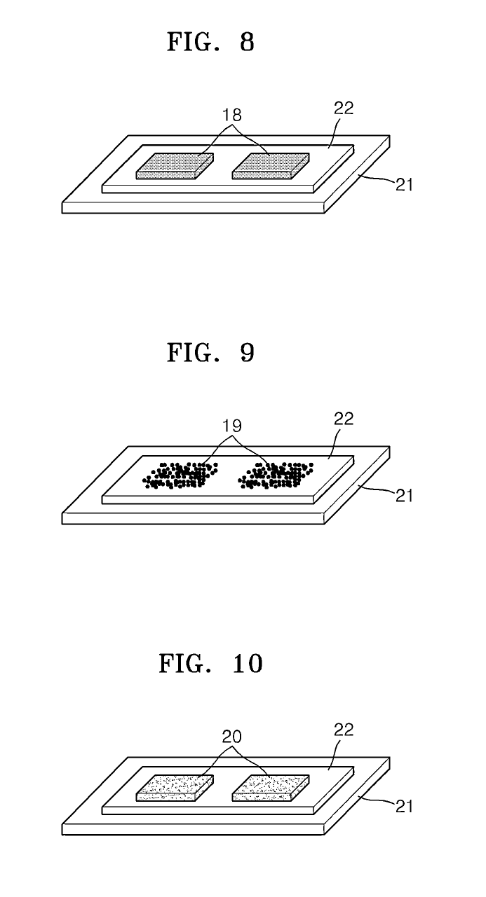

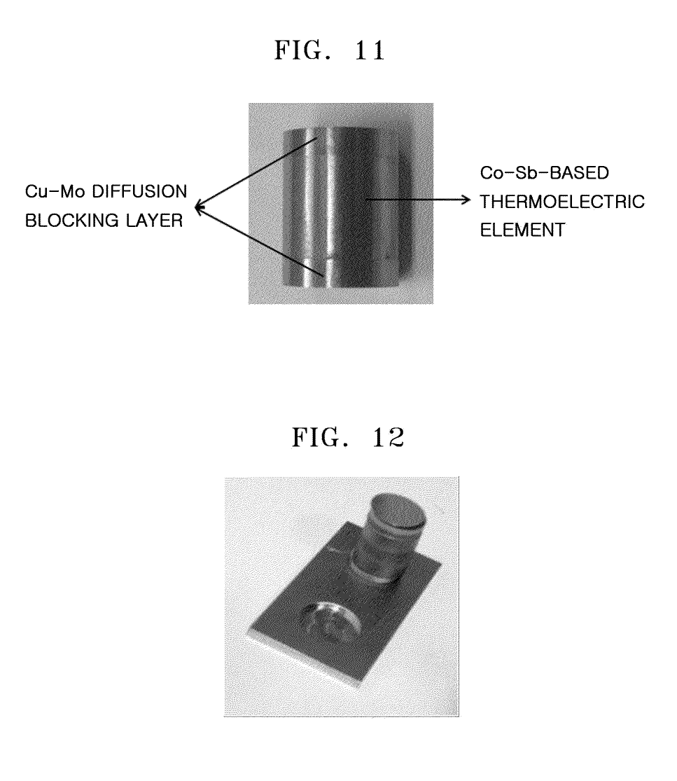

Various forms may be used for the bonding material 17. For example, a bulk form, a powder form, and a paste form may be used. In FIGS. 8 through 10, various forms of the bonding material 17 are shown. In FIG. 8, a bulk form bonding material 18 is illustrated, in FIG. 9, a powder form bonding material 19 is illustrated, and in FIG. 10, a paste form bonding material 20 is illustrated.

Thermoelectric modules may be used in various thermoelectric devices. When supplying electrical energy to the electrical module, the thermoelectric module may be used as a cooling element, for example, used in a non-refrigerant refrigerator, widely used cooling devices such as an air conditioner, and a micro cooling system. Also, when heat energy is supplied using a heat source, electrical energy may be generated such that the thermoelectric module may be useful for exhaust heat power generation or thermoelectric nuclear power generation for military aerospace applications.

The thermoelectric module may be manufactured by the method including: disposing a top and a bottom electrode on a top substrate and on a bottom substrate, respectively; disposing a bonding material on at least one of the top electrode and the bottom electrode; interposing the p-type thermoelectric element between the top electrode and the bottom electrode, each of the p-type thermoelectric element and the n-type thermoelectric element having a diffusion blocking layer disposed thereon, the diffusion blocking layer bonded, e.g., coupled, integrally to each of a top surface and a bottom surface of the p-type thermoelectric element and to each of a top and a bottom surface of the n-type thermoelectric element, wherein the diffusion blocking layer contacts the bonding material if present, to form an electrode structure; and calcining the electrode structure to manufacture the thermoelectric module, wherein the bonding material comprises an amorphous metal.

Each process is further described as below:

First, as shown in FIG. 2, a plurality of the top electrode 12 is patterned on the top substrate 11. Herein, a groove 13 may be formed on the surface of the top electrode 12.

The top substrate 11 may comprise an insulating ceramic, such as alumina (Al₂O₃), aluminum nitride (AlN), boron nitride (BN), or zirconia (ZrO₂). The material used for the top electrode 22 may be selected variously from copper (Cu) which provides high electrical conductivity, copper-molybdenum (Cu—Mo), silver (Ag), gold (Au), and platinum (Pt), and the size of the top electrode 22 may also be selected variously.

The patterning method of the top electrodes 12 may use, without restriction, any suitable patterning method. For example, deposition methods such as a direct bonding method, an e-beam coating method, and a method using a bonding agent such as AgPd may be used. A plurality of the top electrodes 12 are divided into numerous pieces.

A method of forming a groove 13 on the plurality of top electrodes 12, may include, but is not limited to, mechanical method such as punching or a chemical method such as etching.

Subsequently, a bonding material is added for bonding on the top electrode 12, for example, bonding to the groove 13, and the bonding material used may include an amorphous metal. The bonding material may be used in a sufficient quantity for bonding the thermoelectric element.

Thereafter, a p-type thermoelectric element 15 and an n-type thermoelectric element 16, wherein a diffusion blocking layer is integrally coupled, are aligned corresponding to the groove 13 where the bonding material is formed. The alignment is such that the p-type thermoelectric element 15 is on one side of the electrode and the n-type thermoelectric element 16 is on the other side of the electrode, and the aligning of these two thermoelectric elements on the top electrode 12 may be performed by a manual process or by an automated process using a robot.

The p-type thermoelectric element 15 and the n-type thermoelectric element 16, wherein the diffusion blocking layer 14 is integrally coupled, may be manufactured by using a plasma calcination method, hot pressing, hot extrusion, and hot pausing, but is not limited thereto, and may use any suitable method known in the field.

For example, manufacturing a thermoelectric semiconductor element wherein the diffusion blocking layer 14 is integrally coupled to the top and the bottom surfaces of the thermoelectric elements 15 and 16 using a discharge plasma sintering method, may include a manufacturing process which comprises:

in a graphite or a carbon mold, consecutively disposing a top diffusion blocking layer powder, a powder for the thermoelectric element, and bottom diffusion blocking layer powder;

condensing the materials in the graphite or carbon mold to manufacture a bottom diffusion blocking layer particulate material, and a thermoelectric element particulate material within the graphite or carbon mold;

placing the mold formed above including the diffusion blocking layer particulate material and the thermoelectric element particulate material in the discharge plasma sintering chamber;

intermittently warming and pressurizing the product under a vacuum in order to maintain the temperature and the pressure desired to compress and mold the bottom diffusion layer particulate material and the thermoelectric element particulate material; and

rapidly chilling the compressed and molded diffusion blocking layer particulate material and thermoelectric element particulate material to manufacture a thermoelectric element having the diffusion blocking layer integrally coupled on the top and on the bottom surfaces of the thermoelectric element.

The process of intermittently warming and pressurizing the particulate material may involve, for example, an intermittent warming up to a temperature of about 400° C. to about 650° C. or about 500° C. to about 600° C., pressuring the product up to a pressure of about 30 megaPascals (MPa) to about 70 MPa, specifically about 40 MPa to about 60 MPa.

As a different method, it is also possible to manufacture the thermoelectric element by the plasma sintering method, and to further manufacture the diffusion blocking layer and bonding the layer by a pressure and heat treatment. Also, the diffusion blocking layer may be manufactured by thermal spray.

According to an embodiment, the pressure molding process used in the manufacturing process above may be performed by additionally maintaining the intermittent warming temperature and the pressurizing pressure, for a prescribed amount of time.

The diffusion blocking layer is used to prevent a component of an electrode component from diffusing in the direction of the thermoelectric element, and a metal suitable in terms of bonding efficiency with the electrode may be used for the diffusion blocking layer. For example, the diffusion blocking layer may comprise at least one selected from Ti, Pt, Pd, Ti, W, Ni, Si, Ta, TiW, TiN, WN, TaN, and TiWN. The diffusion blocking layer may further or alternatively comprise at least one selected from a silicide of Ti, Pt, Pd, Ti, W, Ni, and Ta.

As the thermoelectric element, the thermoelectric semiconductor element may be used as the thermoelectric element.

Apart from the top substrate 21 where the top electrode 12 is patterned, a plurality of the bottom substrates 21 where the bottom electrodes 22 are patterned may be manufactured by using the same method, and the bottom groove 23 may be formed on the bottom electrode 22 using the same method for manufacturing the top electrode groove 13. A plurality of the bottom electrodes 22 inclusive of the concave bottom grooves 23 and patterned on the bottom substrate 21 is illustrated in FIG. 3. The end of the bottom substrate 21 includes a lead electrode 24 connected to the bottom electrode 22.

In the bottom electrode 22, for example, the amorphous metal bonding material is disposed into each of the bottom groove 23, and coupled to the p-type thermoelectric element 15 and the n-type thermoelectric element 16 arranged in the top substrate 11. In the coupling process, the bottom groove 23 is coupled such that the location of the groove 23 matches the locations of the p-type thermoelectric element 15 and the n-type thermoelectric element 16.

The bonding material includes the amorphous metal, and may be used in various forms. For example, the bonding material may be used in a bulk form or in a powder form. If the bonding material is used in a paste form, the bonding material may be used by preparing a paste composite, and in addition to the amorphous metal, the paste composite may further contain silver, copper, molybdenum, organic solvent, and binder. Each of the above may be used in a volume ratio of 50% of each of a metal component and an organic component of an organic solvent and a binder, wherein the metal component may be at least one selected from the amorphous metal, silver, copper, and molybdenum, for example.

When the coupling is completed, the thermoelectric element is coupled at the top surface and the bottom surface of the substrate 21 by calcination, thereby completing the thermoelectric module.

The calcination process that bonds the thermoelectric electrode and the thermoelectric electrode, wherein the diffusion blocking layers are integrally bonded, may be performed at a temperature of about 450° C. to about 600° C., or about 500° C. to about 600° C. for about 1 minute to about 10 minutes.

It should be understood that the exemplary embodiments described herein should be considered in a descriptive sense only and not for purposes of limitation. Descriptions of features, advantages or aspects within each embodiment should be considered as available for other similar features or aspects in other embodiments.

### EXAMPLES

### Example 1

Using the Co—Sb type thermoelectric material Ba_{0.08}La_{0.05}Yb_{0.04}Co₄Sb₁₂, a cylindrical thermoelectric element with a diameter of 10 mm and a height of 10 mm is manufactured using a plasma calcination method, wherein a Cu—Mo alloy layer as the diffusion blocking layer was bonded by a pressure heat treatment. The applied pressure was 500 MPa, and the heat treatment temperature was maintained at 650° C. for 10 minutes.

FIG. 11 illustrates a side view photograph of a Co—Sb type thermoelectric element with a Cu—Mo diffusion blocking layer manufactured by the process.

In a copper (Cu) electrode in which a groove is formed at an area where the thermoelectric element is bonded, Al₈₅Ni₅Co₂Y₈ is charged as an amorphous alloy, and the thermoelectric element where the diffusion blocking layer is bonded is located on the groove. Thereafter, pressure heat treatment was performed at a temperature of 600° C. for 5 minutes at a pressure of 300 MPa to bond the thermoelectric element and the electrode. The obtained electrode structure is illustrated in FIG. 12.

### Example 2

Manufacturing an electrode structure was performed in the same manner as in Example 1, except for using a silver paste including an amorphous metal instead of an amorphous alloy, and maintaining the heat treatment for bonding at a temperature of 650° C. for 5 minutes.

The silver paste including an amorphous alloy was prepared by adding an amorphous alloy Al₈₅Ni₅Co₂Y₈ to the silver paste at a weight ratio of 2%. As the silver paste, a composition with a silver content having a weight ratio of 60%, the organic solvent terpineol having a weight ratio of 28%, and ethylcellulose binder having a weight ratio of 12% was used, each based on a total weight of the silver paste.

### Comparative Example 1

A cylindrical thermoelectric element was manufactured using a Co—Sb type thermoelectric element Ba_{0.08}La_{0.05}Yb_{0.04}Co₄Sb₁, using a plasma calcination method.

### Comparative Example 2

Manufacturing an electrode structure was performed in the same manner as in Example 1, except for using a silver paste including an amorphous metal instead of an amorphous alloy, and maintaining the heat treatment for bonding at a temperature of 650° C. for 5 minutes.

As the silver paste, a composition having a silver content in a weight ratio of 60%, the organic solvent terpineol in a weight ratio of 28%, and ethylcellulose binder in a weight ratio of 12% was used, each based on a total weight of the silver paste.

### Example 1

### Electrical Resistance Measurement Test

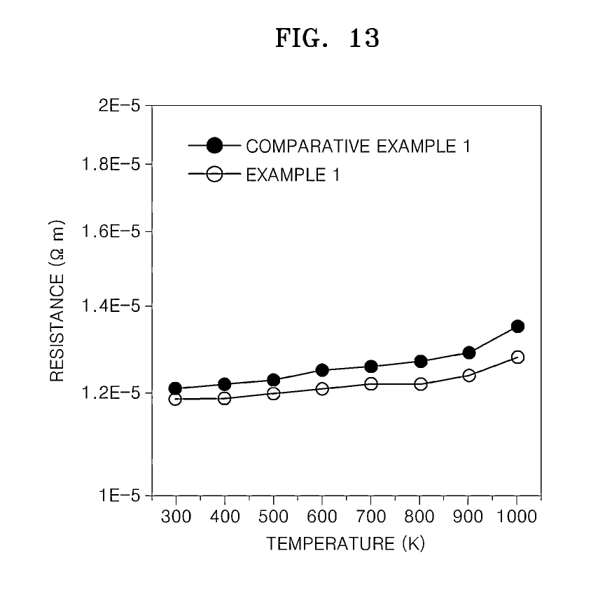

The electrical resistance of (1) a Co—Sb type thermoelectric element in Comparative Example 1, and (2) an electrode structure obtained in Example 1, wherein the electrode structure has a Co—Sb type thermoelectric element bonded with an amorphous alloy bonding layer, was measured by using a 4-probe DC measurement, shown in FIG. 13. As shown in FIG. 13, resistance corresponding to the temperature of Co—Sb type thermoelectric elements did not show a great change after adhering a Cu—Mo diffusion blocking layer, an amorphous alloy bonding layer and a Cu electrode. This illustrates that the amorphous alloy bonding layer has a sufficient electrical conductivity and that the bonding site bonded without any resultant defect such as an air space.

### Example 2

### Bonding Strength Measurement Test

To measure bonding strength, a sample bonded with the silver paste in Comparative Example 2, and a sample bonded with a silver paste including an amorphous alloy in Example 2 were prepared and measured with respect to a 3-point bending strength at a room temperature.

When measuring the strength, broken bonds appeared at the weakest points, namely, at a bonding layer between the diffusion blocking layer and the electrode. Bending strength of Comparative Example 1 was below 10 MPa when silver paste was used for bonding, which is much lower than the bonding strength of the Co—Sb type thermoelectric element, which is about 130 MPa. Low bonding strength accompanies a broken bond caused by thermal stress when operating the thermoelectric module. On the other hand, when bonding using the silver paste including the amorphous alloy in Example 2, the bonding strength was greater than 50 MPa such that the bonding strength increased by more than 5 fold compared to when the silver paste was used.

What is claimed is:

1. A thermoelectric module comprising:
an n-type thermoelectric element;
a p-type thermoelectric element;
a diffusion blocking layer bonded integrally on at least one of a top and a bottom surface of the n-type thermoelectric element and on at least one of a top and a bottom surface of the p-type thermoelectric element;
an electrode on the n-type thermoelectric element and on the p-type thermoelectric element; and
a bonding layer disposed between the electrode and at least one of the n-type thermoelectric element and the p-type thermoelectric element,
wherein the bonding layer comprises an amorphous metal.

2. The thermoelectric module of claim 1, wherein a glass transition temperature of the amorphous metal is less than a melting point of a thermoelectric material of the n-type thermoelectric element and less than a melting point of a thermoelectric material of the p-type thermoelectric element.

3. The thermoelectric module of claim 1, wherein the amorphous metal comprises at least one selected from aluminum (Al), copper (Cu), nickel (Ni), magnesium (Mg), manganese (Mn), calcium (Ca), zirconium (Zr), iron (Fe) and titanium (Ti).

4. The thermoelectric module of claim 1, wherein the amorphous metal is an Al alloy or a Cu alloy.

5. The thermoelectric module of claim 1, wherein an amount of the amorphous metal is about 5 weight percent to about 90 weight percent, based on a total weight of the bonding layer.

6. The thermoelectric module of claim 1, wherein a thickness of the bonding layer is about 5 micrometers to about 10 micrometers.

7. The thermoelectric module of claim 1, wherein the n-type thermoelectric element and the p-type thermoelectric element each comprise a thermoelectric semiconductor comprising at least two elements selected from a transition metal, a rare earth element, a Group 13 element, a Group 14 element, a Group 15 element, and a Group 16 element.

8. The thermoelectric module of claim 1, comprising about 50 to about 200 thermoelectric couples, wherein each of the about 50 to about 200 thermoelectric couples comprises one of the p-type thermoelectric element and one of the n-type thermoelectric element.

9. A thermoelectric device comprising the thermoelectric module of claim 1.

10. The thermoelectric device of claim 9, wherein the thermoelectric device is a cooling element or a power generating element.

11. A thermoelectric device comprising:
the thermoelectric module of claim 1.

12. The thermoelectric device of claim 11 comprising
a heat absorbing part;
a heat emitting part; and
wherein thermoelectric module contacts the heat absorbing part and the heat emitting part.

13. A method of manufacturing a thermoelectric module, the method comprising:
disposing a top electrode and a bottom electrode on a top substrate and a bottom substrate, respectively;
disposing a bonding material on at least one of the top electrode and the bottom electrode;
interposing a p-type thermoelectric element and an n-type thermoelectric element between the top electrode and the bottom electrode, each of the p-type thermoelectric element and the n-type thermoelectric element having a diffusion blocking layer disposed thereon, the diffusion blocking layer bonded integrally to each of a top and a bottom surface of the p-type thermoelectric element and to each of a top and a bottom surface of the n-type thermoelectric element, wherein the diffusion blocking layer contacts the bonding material if present, to form an electrode structure; and
calcining the electrode structure to manufacture the thermoelectric module,
wherein the bonding material comprises an amorphous metal.

14. The method of claim 13, wherein the amorphous metal is in at least one selected from a bulk form, a powder form, and a paste form.
